(19) United States
(12) Patent Application Publication
(10) Pub. No.: US 2014/0377958 A1
(43) Pub. Date: Dec. 25, 2014

(54) PLASMA PROCESSING METHOD AND VACUUM PROCESSING APPARATUS

(71) Applicant: Hitachi High-Technologies Corporation, Tokyo (JP)

(72) Inventors: Kazuumi Tanaka, Tokyo (JP); Masahiro Sumiya, Tokyo (JP)

(73) Assignee: Hitachi High-Technologies Corporation, Tokyo (JP)

(21) Appl. No.: 14/180,552

(22) Filed: Feb. 14, 2014

(30) Foreign Application Priority Data
Jun. 25, 2013 (JP) 2013-132210

(51) Int. Cl. H01L 21/3065; H01L 21/67

(52) U.S. Cl. CPC H01L 21/3065; H01L 21/67069
USPC 438/710; 156/345.31

(57) ABSTRACT

A plasma processing method embodying this invention is for applying plasma processing to a sample having a metal-containing film. This method includes the steps of applying plasma processing to the sample by using a mixture of halogen-containing gas and nitrogen gas, generating a plasma using a mixture of oxygen gas and inert gas in a plasma production chamber, which is different from a post-treatment chamber used for posttreatment of the plasma-processed sample, and performing posttreatment of the sample while at the same time transporting the generated plasma to the posttreatment chamber via a transfer path disposed between the plasma production chamber and the posttreatment chamber.

### BACKGROUND OF THE INVENTION

The present invention relates to a plasma processing method and vacuum processing apparatus. More particularly, this invention relates to a plasma processing method for manufacturing semiconductor devices and a vacuum processing apparatus for use by the method.

In semiconductor manufacturing/fabrication processes, dry etching using a plasma is generally performed, which has a critical issue as to how to reduce foreign matter that badly behaves to lower manufacturing yields. In addition, the quest for higher integration in semiconductor devices leads to miniaturization of on-chip circuit elements, resulting in a decrease in grain size of foreign matter that lowers yields. Thus, the demand for reduction of foreign matter is increasing more and more.

Examples of the foreign matter attachable to a workpiece or sample in vacuum processing apparatus include, but not limited to, contaminant particles attached to the inner wall of vacuum apparatus, contaminants produced from the inner wall per se due to corrosion of an inner wall material of the vacuum apparatus and fallen onto a wafer in the course of sample transportation and vacuum evacuation, and residual by-products created by plasma etching treatment.

One of the latter cause is the presence of halogen components remaining on a sample. As is generally known, such residual halogen components on the sample cause corrosion of inner walls of the apparatus except a processing chamber(s) in the process of transporting the sample. It is also known that they create contaminants on the sample by the presence of byproducts due to admixture with other gases.

For example, it is known that an ammonium halide acting as contaminant is produced on a sample surface during processing by mixing or blending together a nitrogen (N₂) gas and a halogen-containing gas, such as chlorine (Cl₂) gas, hydrogen bromide (HBr) gas or else, and a nitrogen gas and that the ammonium halide can often impair the etching treatment to be next executed. As is also known, residual bromine (Br) increases on a substrate after transportation into the atmospheric air and badly behaves to bury a pattern formed.

As a corrosion prevention method for use in transportation systems, JP-A-2006-270030 discloses therein a plasma processing method which performs plasma processing with respect to an object to be processed in a chamber. This method includes first plasma processing for treating the to-be-processed object using a first plasma generated by plasmanization of a gas that contains at least halogen elements, second plasma processing for supplying, after the first plasma processing, an oxygen-containing gas into the chamber to thereby generate a second plasma and for processing the chamber and the to-be-processed object, and third plasma processing for processing the to-be-processed object after the second plasma processing by a third plasma created by plasmanization of a gas that contains at least fluorine.

Additionally, JP-A-2008-109136 (corresponding to U.S. Pat. No. 7,846,845) discloses therein a method for removing volatile residues from a substrate, which method includes the steps of preparing a processing system having a vacuum airtight platform, processing the substrate by a halogen-containing chemical in a processing chamber of the platform, and treating the processed substrate within the platform to thereby release the volatile residues from the processed substrate.

### SUMMARY OF INVENTION

In recent years, metallic materials are used as semiconductor device materials in transistor structures, such as high-dielectric-constant (“high-k”)/metal-gate structures for example. In spite of the fact that these metal materials become surface-oxidized by exposure to an oxygen (O₂) plasma and thus degrade device characteristics, the plasma processing method disclosed in JP-A-2006-270036 fails to take into consideration the risk of metal material surface oxidation.

This invention provides a plasma processing method for applying plasma etching to a metallic material using a halogen gas, which is capable of suppressing metal material surface oxidation and removing residual halogen components on samples, and also provides a vacuum processing apparatus for use by the method.

In accordance with one aspect of this invention, a plasma processing method for applying plasma processing to a sample having a film containing a metal therein is provided. This method includes the steps of performing plasma processing of the sample by using a mixture of a halogen-containing gas and a nitrogen gas, generating a plasma by use of a mixture of an oxygen gas and an inactive gas in a plasma production chamber being different from a posttreatment chamber for use in execution of posttreatment with respect to the plasma-processed sample, and performing posttreatment of the sample while simultaneously transporting the generated plasma to the posttreatment chamber through a transfer path disposed between the plasma production chamber and the posttreatment chamber.

In accordance with another aspect of the invention, a vacuum processing apparatus is provided which includes a plasma processing chamber for applying plasma processing to a sample, an unload lock chamber for carrying the plasma-processed sample out of the chamber to an atmosphere side, and a remote plasma device for generating a plasma in a plasma production chamber different from the plasma processing chamber and also from the unload lock chamber. The unload lock chamber is arranged to have therein the remote plasma device and to perform posttreatment of the plasma-processed sample.

One major advantage of this invention is as follows: in a plasma processing method which applies plasma etching to a metal material using halogen gas and a vacuum processing apparatus used thereby, it is possible to suppress the metal material surface oxidation and remove residual halogen components on samples successfully.

Other objects, features and advantages of the invention will become apparent from the following description of the embodiments of the invention taken in conjunction with the accompanying drawings.

### BRIEF DESCRIPTION OF DRAWINGS

FIG. 1 is a diagram schematically showing a vacuum processing apparatus in accordance with one embodiment of the present invention.

FIG. 2 is a diagram showing, in cross-section, an unload lock chamber in accordance with an embodiment of this invention.

FIG. 3 is a diagram graphically showing a relation of a hydrogen bromide (HBr) gas-created contaminant number versus chlorine (Cl₂) gas-created contaminant number.

FIG. 4 is a graph with bar charts each showing a composition of elements remaining on the surface of a titanium nitride film.

FIG. 5 is a graph showing a dependency curve of the residual percentage of oxygen elements remaining on the surface of a titanium nitride film with respect to a dilution ratio of oxygen gas.

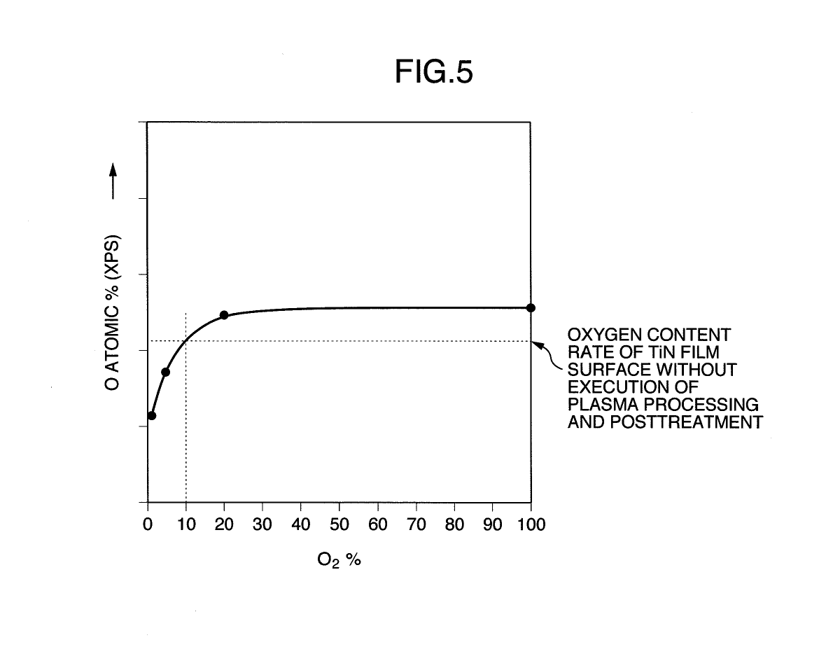

### DETAILED DESCRIPTION OF EMBODIMENTS

Embodiments of this invention will be described in detail with reference to the accompanying drawings below.

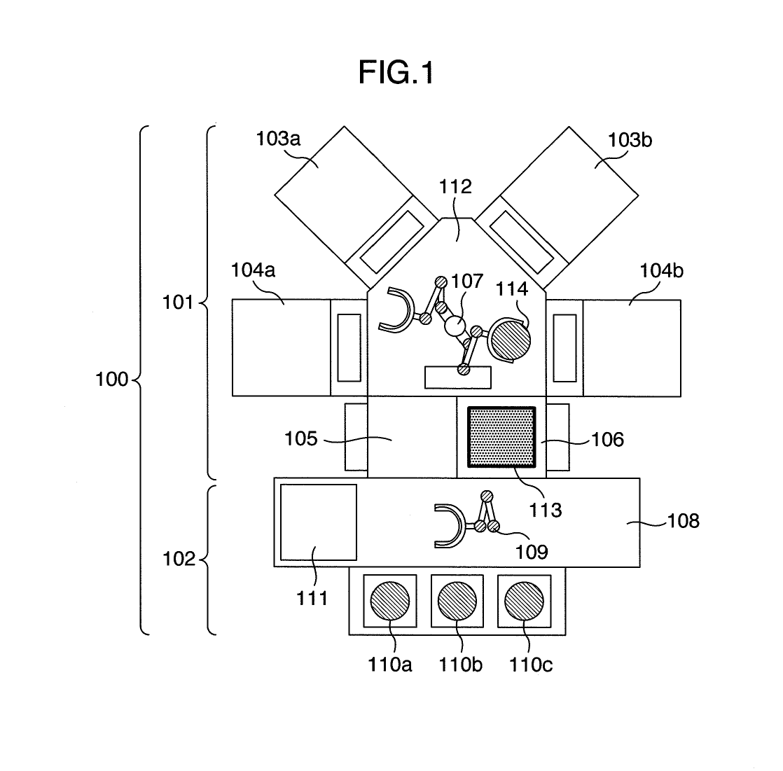

Firstly, an outline of vacuum processing apparatus 100 incorporating the principles of this invention will be explained using FIG. 1. As shown herein, the vacuum processing apparatus 100 is generally made up of two main parts: a vacuum-side block 101 and an ambient air-side block 102. The air-side block 102 has an atmospheric transfer chamber 108 with an atmospheric transfer robot 109 built therein, and an alignment unit 111. On the front face side of this atmospheric transfer chamber 108, there are provided wafer cassettes 110a, 110b and 110c each capable of accommodating a plurality of samples, such as semiconductor wafers to be processed in the vacuum processing apparatus 100.

The vacuum-side block 101 includes vacuum processing chambers 103a and 103b which are provided around the side wall of a vacuum-side transfer chamber 112 that internally has a vacuum transfer robot 107, for allowing a sample 114 to be carried into its pressure-reduced interior space and for executing etching treatment of the sample, plasma post-treatment chambers 104a-104b for use in applying posttreatment, such as ashing, to the sample sent to its pressure-reduced inside space, and a pair of load lock chamber 105 and unload lock chamber 106 for moving sample 114 between the air side and the vacuum side.

In this embodiment, the vacuum processing chamber 103a, 103b disposed in vacuum processing apparatus 100 shown in FIG. 1 has a vacuum vessel (not shown), a gas supply device (not shown) which is coupled to the vacuum vessel, a vacuum evacuation system (not shown) which maintains the internal pressure of vacuum vessel at a desired value, a sample table (not shown) for mounting thereon the sample 114 that is a semiconductor substrate, and a plasma generating unit (not shown) for generating a plasma in the vacuum processing chamber 103a, 103b. The vacuum processing chamber 103a, 103b converts by the plasma generating unit a processing gas that was supplied from a shower plate (not shown) opposing the sample table to the interior of vacuum processing chamber 103a, 103b in a down-flow manner to a plasma state, thereby performing plasma processing of the sample held on the table.

The plasma generating unit of this embodiment may typically be a plasma generator device of the type forming efficiently a plasma of reactive gas within the vacuum processing chamber 103a, 103b by electron cyclotron resonance (ECR) of a microwave introduced into vacuum processing chamber 103a, 103b and a magnetic field created by a solenoid coil disposed around the vacuum processing chamber 103a, 103b. This device is called the microwave-ECR plasma generator.

The plasma posttreatment chamber 104a, 104b disposed in the vacuum processing apparatus 100 shown in FIG. 1 includes a vacuum vessel (not shown), a gas supply device (not shown) coupled to the vacuum vessel, a vacuum evacuation unit (not shown) for keeping the internal pressure of vacuum vessel at a desired value, a sample table (not shown) for holding thereon the sample 14, e.g., a semiconductor substrate, and a plasma generating unit (not shown) for creating a plasma.

The plasma posttreatment chamber 104a, 104b performs plasma processing of the sample being mounted on the sample table by causing, with the aid of plasma generating unit, a processing gas that was fed from a shower plate (not shown) opposing the sample table to the interior of plasma posttreatment chamber 104a, 104b in a down-flow manner to go into a plasma state. Note here that the plasma generating unit is the one that creates a plasma different from the plasma created in vacuum processing chamber 103a, 103b. To accelerate desorption reaction by ashing treatment, the sample table internally has a heater. Also note that the plasma posttreatment chamber 104a, 104b employs as its plasma generating unit a plasma generator of the type having an inductively-coupled plasma source.

The embodiment apparatus further includes a remote plasma device 113 in the unload lock chamber 106. The remote plasma device 113 used in this embodiment is a plasma generating device which does not perform plasma processing to be applied to the sample 114 in remote plasma device 113. Unlike the unload lock chamber 106 that holds sample 114 therein, the remote plasma device 113 has a plasma production chamber (not shown) having its inner wall made of a corrosion resistivity-enhanced material, such as quartz, aluminum with its surface having been applied oxidation treatment or else, by way of example. To this plasma production chamber, a predetermined kind of gas is fed at a prespecified flow rate. By supplying predetermined radio-frequency power at predefined pressure, a plasma is created in the chamber.

The plasma generated in the plasma production chamber is transported via a vacuum pipe (not shown) to the unload lock chamber 106 with sample 114 being placed therein; thus, an activated reactive gas, acting as a radical, reaches a top surface of sample 114. This is done because of the following. Although the plasma created in the plasma production chamber contains ions and radicals, most ions—i.e., charged particles—disappear due to collision with the wall of the vacuum pipe in the process of transporting the plasma created in the plasma production chamber to the unload lock chamber via vacuum pipe, resulting in radicals mainly arriving at unload lock chamber 106.

Additionally, by generating a plasma while setting the pressure of the plasma production chamber at a relatively high pressure, e.g., 100 Pa or above, it becomes possible to facilitate diminishing of the arrival of ions at unload lock chamber 106, thus making it possible to transfer radicals to unload lock chamber 106 efficiently. While examples of the plasma generating unit of the plasma production chamber include various types of plasma sources, such as direct-current (DC) discharge, capacitively-coupled radio-frequency discharge, inductively-coupled radio-frequency discharge, and microwave discharge, it is preferable, from a viewpoint of lowness of discharge-caused impurity mixture, to employ a plasma source of the electrodeless discharge type having no electrodes in the plasma production chamber, such as plasma sources of the inductively-coupled radio-frequency discharge type and microwave discharge type.

Although the plasma generation in the plasma production chamber is achievable at any pressures ranging from low pressure of 1 Pa or below to the atmospheric pressure, it is desirable to set the plasma generation pressure to a relatively high pressure of 100 Pa or above in a viewpoint of reduction of both the efficiency of radical production and the arrival factor of ions at load lock chamber 106 as stated previously.

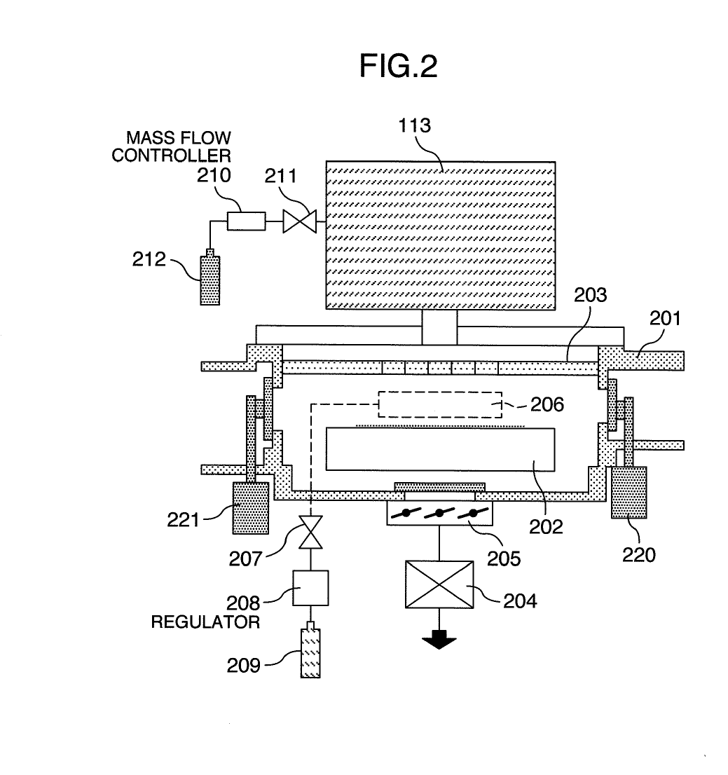

Referring next to FIG. 2, there are shown a cross-sectional structure of the unload lock chamber 106 having remote plasma device 113 and its peripheral equipment. The unload lock chamber 106 has several constituents disposed therein, including a vacuum vessel 201 made of aluminum or surface-oxidized aluminum, a sample table 202 for mounting thereon a sample that is an object to be processed, and a shower plate 203 made of quartz opposing the table. The shower plate 203 may be made of aluminum or surface-oxidized aluminum.

The unload lock chamber 106 is equipped with an evacuation device 204 for depressurization of the vacuum vessel 201 and serves to control the exhaust velocity of the evacuator 204 by means of an operative valve 205 provided between the evacuator 204 and unload lock chamber 106, thereby to control the internal pressure of vacuum vessel 201. In this embodiment, the evacuator 204 is a dry pump.

To the unload lock chamber 106, a vent gas is introduced from a vent gas supply unit 209 through a gas diffuser 206, a vent valve 207 and a regulator 208. The unload lock chamber 106 is hermetically isolatable from the atmospheric transfer chamber 108 by closing an atmospheric-side gate valve 220 and isolatable from vacuum-side transfer chamber 112 by closing a vacuum-side gate valve 221.

The remote plasma device 113 is placed at upper part of the unload lock chamber 106. To the remote plasma device 113, a process gas is fed from a process gas supply device 212 through a mass flow controller 210 and gas valve 211, for generating a plasma. This results in radicals chiefly reaching unload lock chamber 106. Those radicals created in remote plasma device 113 are irradiated onto the target sample via the shower plate 203. Although one specific example with the remote plasma device 113 being built in unload lock chamber 106 was explained in this embodiment, similar effects are also obtainable when the remote plasma device 113 is built in the plasma posttreatment chamber 104a, 104b.

A plasma processing method embodying the invention will next be described. Principally, this method includes preparing a sample to be processed (e.g., silicon wafer in this embodiment) which sample was subjected in advance to measurement of the number of attached contaminants, applying etching to this sample under conditions using a mixture of a gas containing therein a halogen component such as hydrogen bromide (HBr), chlorine (Cl₂), etc. and inactive or inert gases of nitrogen (N₂) and argon (Ar), measuring again the contaminant number after execution of the etching, and checking the sample to determine if contaminant production is found. Preferably the contaminant number measurement after the etching is performed two times in total—i.e., just after the etching, and 24 hours later.

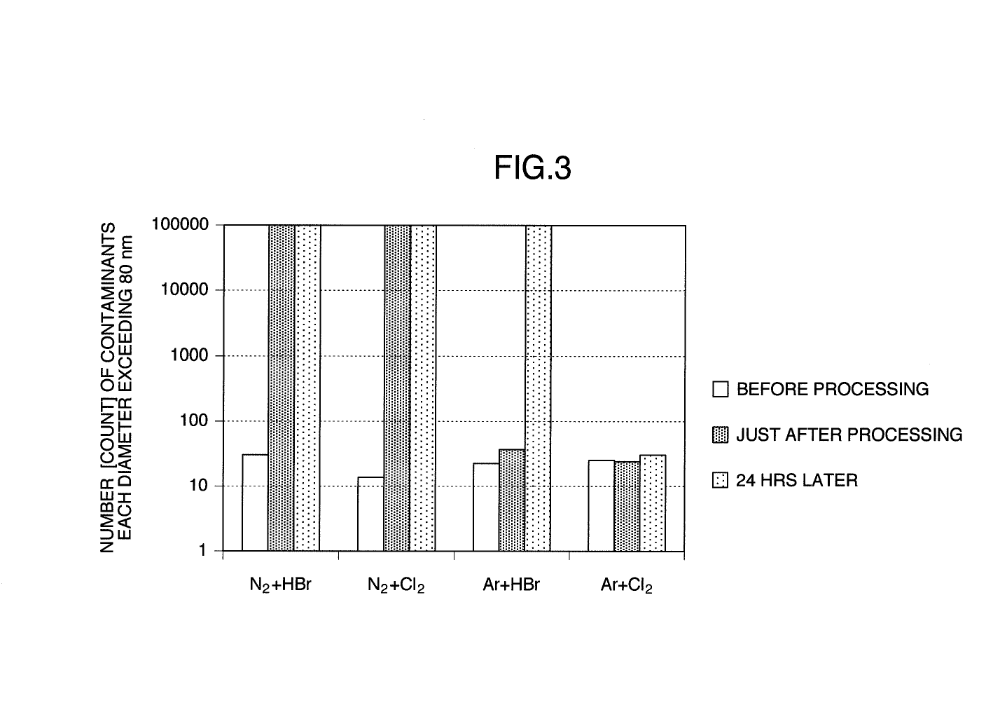

In this embodiment, the flow rate of the HBr/Cl₂ halogen-containing gas was set to 150 milliliters per minute (ml/min) whereas the flow rate of Ar and N₂ inert gases was set at 50 ml/min. See FIG. 3, which shows contaminant number measurement results after the etching treatment using a mixture of one of hydrogen bromide (HBr) and chlorine (Cl₂) gases and one of nitrogen (N₂) and argon (Ar) inert gases. In this figure, the ordinate represents the number of contaminants each exceeding 80 nm in its grain size (diameter). In a combination of halogen-containing gas and N₂, it became overflow (measurement inexecutable) immediately after the treatment.

In a combination of halogen-containing gas and Ar, the Cl₂ is free from the contaminant production; however, the HBr exhibited an increase of about several tens of contaminants in the measurement immediately after the etching treatment and, in the measurement performed 24 hours later, it became overflow (measurement inexecutable). This revealed that the production tendency is different depending on the kind of the halogen used. It was also ascertained that contaminants produced differ in type although a detailed discussion thereof is eliminated herein. Regarding the above-stated contaminants, the former is considered to be generated in the vacuum processing chamber 103a as byproducts based on Br or Cl and N₂ whereas the latter is considered such that residual bromine (Br) attached to the sample behaved to absorb components in the atmosphere to grow as contaminants.

It is ascertained that the byproducts due to the halogen (Br, Cl or else) and nitrogen (N₂) are generated not only in cases where these components are used together at the same step but also in the case of nitrogen (N₂) being used for a very small amount of residual halogen remaining within the vacuum processing chamber 103a and on the sample surface. The etching condition consists of one step or a plurality of steps. As is also ascertained, the above-stated contaminants arise from not only silicon but also respective film materials used for the sample to be etched, such as for example a silicon oxide film, silicon nitride film, titanium nitride film, etc.

In short, growable foreign matter occurs when a sample that was plasma-treated using a mixture of halogen-containing gas and nitrogen gas in the vacuum processing chamber 103a is exposed to the atmospheric air without execution of posttreatment or the like. In a case where the sample that was plasma-treated using a gas mixture of halogen-containing gas and nitrogen gas has a film which contains a metal, a need is felt to pay more careful attention to preventing the metal from being oxidized. In light of these requirements, an explanation will now be given of a plasma processing procedure with a series of processes in accordance with one embodiment of this invention, which is for suppressing residual halogen-based contaminant growth and for deterring metal oxidation.

In the vacuum processing apparatus 100 shown in FIG. 1, the atmospheric transfer robot 109 operates to pick up a sample 114 having a titanium nitride (TiN) film from one of the wafer cassettes 110a, 110b and 110c and then carry it to the alignment unit 111. After having completed alignment of sample 114, this sample is transported to the load lock chamber 105. The sample 114 that was carried into load lock chamber 105 is then placed on the sample table (not depicted) within load lock chamber 105. After the interior of load lock chamber 105 is evacuated and depressurized, vacuum transfer robot 107 transfers it to vacuum processing chamber 103a through vacuum-side transfer chamber 112. In vacuum processing chamber 103a the sample 114 is etched using a mixture of halogen-containing gas and nitrogen gas.

Thereafter, the sample is transferred by vacuum transfer robot 107 to vacuum-side transfer chamber 112 and then to unload lock chamber 106 with built-in remote plasma device 113. In remote plasma device 113, a plasma is generated using a mixture of oxygen and nitrogen gases, followed by execution of posttreatment for exposing radicals—mainly, oxygen radicals—to the sample 114 held in unload lock chamber 106. The rate of content of the oxygen gas in the oxygen/nitrogen gas mixture was set to 1%. The nitrogen gas was used to dilute the oxygen gas.

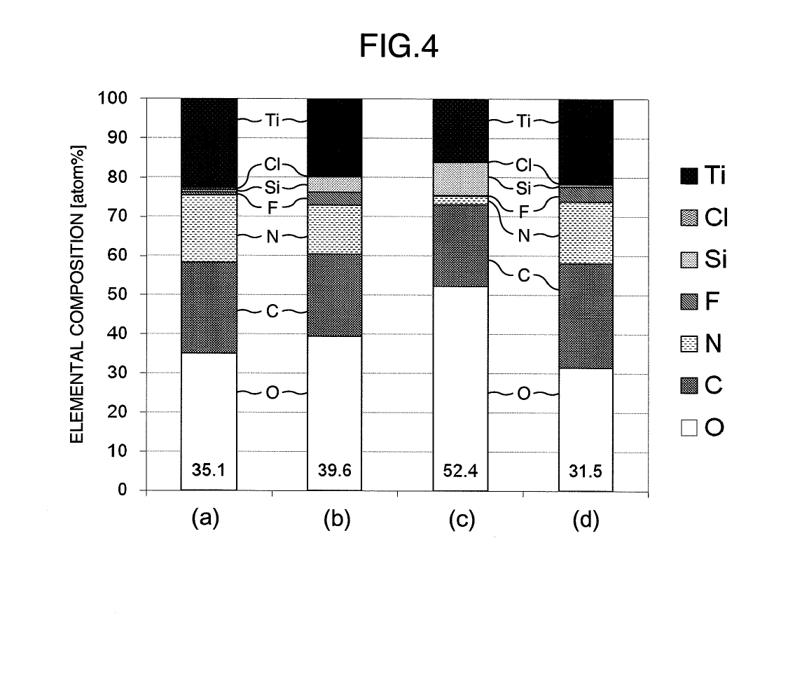

Next, after having vented the unload lock chamber 106, the sample processed is taken out of unload lock chamber 106 by atmospheric transfer robot 109 and returned to its initially stored wafer cassette. With the plasma processing embodying the invention, it was possible to suppress the metal surface oxidation. This may be proven from the following: while part (d) of FIG. 4 shows a composition of elements remaining on the metal surface in the case of execution of the plasma processing of this invention whereas part (a) of FIG. 4 shows a composition of residual elements on titanium nitride film surface in the case of no plasma processing being done, the oxygen content of (d) of FIG. 4 is about the same as that of (a) of FIG. 4.

Part (b) of FIG. 4 shows a composition of residual elements on the titanium nitride film surface in the case of executing only the etching treatment using a mixture of halogen-containing gas and nitrogen gas in vacuum processing chamber 103a; part (c) of FIG. 4 shows a composition of residual elements on the titanium nitride film surface in the event of adding to the case of (b) of FIG. 4 a process of executing posttreatment using a mixture of oxygen and nitrogen gases in plasma posttreatment chamber 104a, with the oxygen gas being diluted to 1%. In the case of (b) of FIG. 4, an effect was seen for suppression of titanium nitride film oxidation;

however, no effect was seen for suppression of growable foreign matter. In the case of (c) of FIG. 4, no effect was seen for suppression of titanium nitride film oxidation; however, an effect was seen for suppression of foreign matter growth.

The above results encourage us to believe that execution of the posttreatment using an oxygen (O₂) gas plasma in plasma posttreatment chamber 104a, 104b serves to cut the coupling of titanium (Ti) and nitrogen (N) in titanium nitride (TiN) by the so-called sputter effect (physical energy) owing to charged particles such as ions, thereby promoting substitution of nitrogen (N) and oxygen (O), resulting in acceleration of surface oxidation reaction. From the foregoing, it is considered that removal of only those residues attached to the surface was enabled without accelerating the sample surface oxidation because radicals chiefly reach the sample surface in remote plasma.

Although in this embodiment the posttreatment in unload lock chamber 106 is arranged to use the mixture of oxygen and nitrogen gases with the oxygen gas being diluted to 1%, the oxygen gas dilution rate should not be limited to 1% and may alternatively be modified to any value chosen from a range of from 1% to 10%. Although in this embodiment the nitride gas was used as a diluent gas of the oxygen gas, this may be replaced with any other suitable inactive or inert gases, such as a helium gas, argon gas, xenon gas, krypton gas, etc.

As has been stated above, this embodiment is arranged to quantitatively control the sample surface-reaching ions and radicals by the remote plasma device that generates either an inductively-coupled plasma or a microwave plasma and the ratio of gases to be introduced into the remote plasma device; however, this invention is such that similar effects to those of this embodiment are obtainable by employing processing conditions and structures for efficient transportation of radicals to the sample surface while preventing ions from reaching the sample surface (i.e., accelerating disappearance) in the capacitively-coupled plasma sources also.

The ion disappearance is promotable by specifically setting the pressure for plasma generation in the above-stated remote plasma processing apparatus to a high level—e.g., 100 Pa to 1 kPa. The efficient transportation of radials is achievable by setting the length of a pass for transferring radicals onto the sample of interest and the cross-section area or aspect ratio of such transfer path to a minimal size which does not affect the transportation of radials, by using as the transfer path's wall material a chosen material that is low in disappearance rate at the time of collision of oxygen radicals—typically, quartz or surface-oxidized aluminum.

Regarding the sample's temperature in the process of posttreatment in unload lock chamber 106, it is desirable in view of the reactivity of residual components on sample surface and radicals to perform the treatment at a temperature which is 20° C. or above and simultaneously lower than or equal to the sample's transition temperature (e.g., glass transition temperature Tg, etc.) at which the sample varies in material characteristics. The reason of this is as follows: at temperatures below 20° C., the reaction of radials with halogen-containing foreign matter abates; at temperatures higher than the transition temperature, the processing of the sample leads to undesired acceleration of the oxidation.

While this embodiment has been described in one specific case where the vacuum processing chamber 103a, 103b is of the type using ECR plasma generator, this is not to be construed as limiting the invention. Other similar ones of the type using an inductively-coupled plasma, capacitively-coupled plasma and the like are also employable as the plasma generator.

Additionally, while the illustrative embodiment has been discussed based on one example with the remote plasma device being mounted above the unload lock chamber 106, this invention permits the remote plasma device to be placed above the load lock chamber 105 and also permits the remote plasma to be used as the plasma source of plasma posttreatment chamber 104a, 104b.

As apparent from the foregoing, one principal feature of this invention is as follows: in a plasma processing method for applying plasma processing to a sample having a film containing a metal therein is provided, the method is arranged to include performing plasma processing of the sample by using a mixture of a halogen-containing gas and a nitrogen gas, generating a plasma by use of a mixture of an oxygen gas and an inactive gas in a plasma production chamber being different from a posttreatment chamber for use in execution of posttreatment with respect to the plasma-processed sample, and performing posttreatment of the sample while simultaneously transporting the generated plasma to the posttreatment chamber through a transfer path disposed between the plasma production chamber and the posttreatment chamber.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing method for applying plasma processing to a sample having a film containing a metal therein, said method comprising the steps of:
performing plasma processing of the sample by using a mixture of a halogen-containing gas and a nitrogen gas;
generating a plasma by use of a mixture of an oxygen gas and an inactive gas in a plasma production chamber being different from a posttreatment chamber for use in execution of posttreatment with respect to the plasma-processed sample; and
performing posttreatment of said sample while simultaneously transporting the generated plasma to said posttreatment chamber through a transfer path disposed between said plasma production chamber and said posttreatment chamber.

2. The plasma processing method according to claim 1, wherein a ratio of the oxygen gas to the mixture of oxygen gas and inactive gas is a ratio capable of suppressing oxidation of said metal.

3. The plasma processing method according to claim 2, wherein the ratio of said oxygen gas to the mixture of oxygen gas and inactive gas is a ratio ranging from 1% to 10%.

4. The plasma processing method according to claim 1, wherein said posttreatment is performed by using a remote plasma device.

5. The plasma processing method according to claim 1, wherein said inactive gas is a nitrogen gas.

6. The plasma processing method according to claim 1, wherein a treatment temperature during execution of the posttreatment is set to a temperature falling within a range of from 20° C. to a transition temperature inherent to a material of said sample.

7. A vacuum processing apparatus comprising:
a plasma processing chamber for applying plasma processing to a sample;
an unload lock chamber for carrying the plasma-processed sample out of said chamber to an atmosphere side; and
a remote plasma device for generating a plasma in a plasma production chamber different from said plasma processing chamber and also from said unload lock chamber, wherein
said unload lock chamber has therein said remote plasma device and performs posttreatment of said plasma-processed sample.

8. The vacuum processing apparatus according to claim 7, wherein said unload lock chamber has a transfer path for transportation of the plasma generated in said plasma production chamber and wherein a material of said transfer path is any one of quartz and aluminum with its surface oxidized.
